(19) United States
(12) Patent Application Publication
(10) Pub. No.: US 2025/0203904 A1
(43) Pub. Date: Jun. 19, 2025

(54) DIFFUSION BARRIER STRUCTURES IN SOURCE/DRAIN STRUCTURES OF NANOSTRUCTURE TRANSISTORS

(71) Applicant: Taiwan Semiconductor Manufacturing Company, Ltd., Hsinchu (TW)

(72) Inventors: Wei Hao LU, Taoyuan (TW); Cheng-Yen WEN, Hsinchu (TW); Chii-Horng LI, Zhubei (TW)

(73) Assignee: Taiwan Semiconductor Manufacturing Company, Ltd., Hsinchu (TW)

(21) Appl. No.: 18/405,967

(22) Filed: Jan. 5, 2024

Related U.S. Application Data
(60) Provisional application No. 63/610,173, filed on Dec. 14, 2023.

(51) Int. Cl. H01L 29/775; H01L 29/06; H01L 29/08; H01L 29/417; H01L 29/423; H01L 29/66; H01L 29/786

(52) U.S. Cl. CPC H10D 30/43; H10D 30/014; H10D 30/6735; H10D 30/6757; H10D 62/121; H10D 62/151; H10D 64/018; H10D 64/258

(57) ABSTRACT

The present disclosure is directed to a structure of a gate-all-around field effect transistors (GAAFET) and a method of forming the structure. The structure includes a diffusion barrier structure in an S/D epitaxial structure of the GAAFET. The diffusion barrier structure is in contact with an NS layer of the GAAFET and extends over side surfaces of inner spacer structures adjacent to the NS layer. The diffusion barrier structure separates a high doping region of the S/D epitaxial structure from the NS layer and regions of the inner spacer structures close to the NS layer. The diffusion barrier structure prevents (or mitigates) dopants in the high doping region from diffusing into the NS layer and the inner spacer structures, preserving the integrity of the NS layer as a semiconducting channel of the GAAFET and avoiding a current crowding effect.

### CROSS-REFERENCE TO RELATED APPLICATION

This patent application claims the benefit of U.S. Provisional Patent Application No. 63/610,173, filed on Dec. 14, 2023 and titled “Diffusion barrier structures in source/drain structures of nanostructure transistors,” which is incorporated by reference herein in its entirety.

### BACKGROUND

Gate-all-around (GAA) field effect transistors (GAAFETs), such as nano-sheet or nano-wire GAAFETs, have improved gate control over their channel regions compared to other types of FETs whose gate structure covers sidewall portions and top surfaces of semiconductor fin structures. Due to their gate-all-around geometry, GAA nano-sheet and nano-wire FETs achieve larger effective channel widths and higher drive currents.

### BRIEF DESCRIPTION OF THE DRAWINGS

Aspects of the present disclosure are best understood from the following detailed description when read with the accompanying figures.

FIG. 1 is an isometric view of a semiconductor device including nanostructure transistors, in accordance with some embodiments.

FIGS. 2A-2C are cross-sectional views of a semiconductor device including nanostructure transistors, in accordance with some embodiments.

FIG. 3A-3C are cross-sectional views of a semiconductor device including nanostructure transistors, in accordance with some embodiments.

FIG. 4 is a flowchart of a fabrication method for the formation of diffusion barrier structures in source/drain epitaxial structures of nanostructure transistors, in accordance with some embodiments.

FIGS. 5 and 6 are isometric views of intermediate structures during the fabrication of diffusion barrier structures in source/drain epitaxial structures of nanostructure transistors, in accordance with some embodiments.

FIGS. 7 through 14B are cross-sectional views of intermediate structures during the fabrication of diffusion barrier structures in source/drain epitaxial structures of nanostructure transistors, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

By way of example and not limitation, nanostructure transistors, like GAA nano-sheet (NS) or nano-wire (NW) FETs (collectively referred to as “GAAFETs”) with nano-sheet (NS) or nano-wire (NW) channel regions, can be formed as follows. A fin-like structure with alternating silicon-germanium (SiGe) and silicon (Si) NS or NW layers is formed on a substrate (e.g., on semiconductor substrate). A sacrificial gate structure is then formed on a middle portion of the fin-like structure to cover top and sidewall surfaces of the fin-like structure so that edge portions of the fin-like structure are not covered by the sacrificial gate structure. The edge portions of the fin-like structure not covered by the sacrificial gate structure are removed. Subsequently, edge portions of the SiGe NS or NW layers are recessed with respect to edge portions of the Si NS or NW layers, and an inner spacer structure is formed by depositing a dielectric material to fill the space formed by the etched portions of the SiGe NS or NW layers. Source/drain (S/D) epitaxial structures are then formed to abut (or to be in contact with) edge portions of the fin-like structures so that the S/D epitaxial structures are in contact with the Si NS or NW layers and isolated (or separated) from the SiGe NS or NW layers by the inner spacer structures. At a later operation, the sacrificial gate structure is removed to expose the top and sidewall surfaces of the fin-like structure. The SiGe NS or NW layers are selectively removed from the fin-like structure. During the selective removal process, the Si NS or NW layers and the inner spacer structures are not removed. Subsequently, a metal gate structure is formed to surround the Si NS or NW layers. Similar to the SiGe NS or NW layers prior to their selective removal, the metal gate structure is isolated (or separated) from the S/D epitaxial structures through the inner spacer structures.

The structure of the GAAFETs may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

In the exemplary GAAFET formed by the process described above, the Si NS or NW layers as channels of the GAAFET can include intrinsic Si or lightly doped Si (e.g., Si with a dopant concentration less than 10¹³ cm⁻³), to provide effective controllability of the conductivity of the channels by a gate bias voltage applied on the metal gate structure. Besides, being intrinsic or lightly doped, the Si NS or NW layers with high purity can facilitate high mobility of charge carriers transporting through the channels, which is beneficial to high-speed operations. On the other hand, the S/D epitaxial structures can include highly doped semiconductor material (e.g., Si with a dopant concentration between about 5×10²⁰ cm⁻³ and about 5×10²¹ cm⁻³) to reduce the resistance of the S/D epitaxial structures, which is beneficial to low power consumption.

Due to the different doping profiles between the Si NS or NW layers and the S/D epitaxial structures, a gradient of doping concentration close to interfaces between the Si NS or NW layers and the S/D epitaxial structures can cause diffusion of dopants from the S/D epitaxial structures into the Si NS or NW layers. The dopants diffusing into the Si NS or NW layers can affect the integrity (e.g., purity) of the Si NS or NW layers, thus lowering the mobility of the charge carriers in the Si NS or NW layers. Moreover, the diffusion of dopants into the Si NS or NW layers can create paths with lowered resistivity, through which charge carriers segregate to pass. Thus, instead of uniformly distributing throughout the cross section of the channels, electrical current locally concentrates along these paths with low resistivity, which is referred to as “current crowding effect” and can impacts the performance of the GAAFET.

In order to prevent (or mitigate) the dopants from diffusing from the S/D epitaxial structures into the Si NS or NW layers, the S/D epitaxial structures can include low doping regions (e.g., with a dopant concentration between about 1×10²⁰ cm⁻³ and about 2×10²¹ cm⁻³) disposed adjacent to the interfaces between the Si NS or NW layers and the S/D epitaxial structures. These additional low doping regions can be referred to as “diffusion barrier structures,” which can reduce the gradient of doping concentration at the interfaces and prevent (or mitigate) the dopants from diffusing directly from high doping regions of the S/D epitaxial structures into the Si NS or NW layers. However, with the diffusion barrier structures covering only the interface between the Si NS or NW layers and the S/D epitaxial structures, the dopants of the high doping regions of the S/D epitaxial structures can still segregate on the inner spacer structures and diffuse through the inner spacer structures into the Si NS or NW layers. These diffusing dopants can not only affect the channels as discussed above, but also introduce defects in the inner spacer structures and degrade the functionality of the inner spacer structures as an isolation between the metal gate structure and the S/D epitaxial structures.

The embodiments described herein are directed to overcome the challenges mentioned above. In some embodiments, a GAAFET can include NS or NW layers, inner spacer structures, and S/D epitaxial structures in contact with the NS or NW layers. The S/D epitaxial structures can include low doping regions as diffusion barrier structures that cover not only interfaces between NS or NW layers and S/D epitaxial structures but also side surfaces of the inner spacer structures. In some embodiments, the S/D epitaxial structures can be formed by epitaxially growing the low doping regions on the NS or NW layers until the low doping regions extend over the side surfaces of the inner spacer structures, follow by epitaxially growing the high doping regions on the low doping regions.

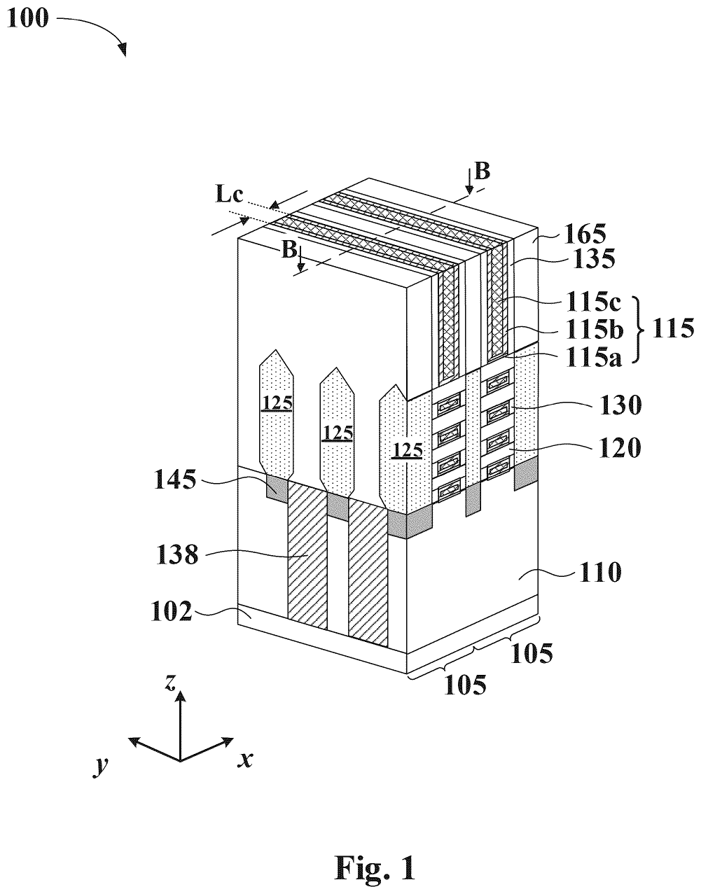

A semiconductor device 100 having multiple GAAFETs 105 formed over a substrate 102 is described with reference to FIG. 1, according to some embodiments. FIG. 1 illustrates an isometric view of semiconductor device 100, according to some embodiments. Semiconductor device 100 can be included in a microprocessor, memory cell, or other integrated circuit (IC). Also, each GAAFET 105 shown in FIG. 1 can be a GAAFET, according to some embodiments.

Referring to FIG. 1, substrate 102 can be a semiconductor material, such as silicon. In some embodiments, substrate 102 can include a crystalline silicon substrate (e.g., wafer). In some embodiments, substrate 102 can include (i) an elementary semiconductor, such as silicon (Si) or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped depending on design requirements (e.g., p-type substrate or n-type substrate). In some embodiments, substrate 102 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 102 can be (100), (110), or (111).

GAAFET 105 can include a fin structure 110 extending along an x-direction, a gate structure 115 traversing through fin structure 110 along a y-direction, and S/D epitaxial structures 125 formed over portions of fin structure 110. Although FIG. 1 shows fin structure 110 accommodating two GAAFETs 105, any number of GAAFETs 105 can be disposed along fin structure 110. In some embodiments, GAAFET 105 can include multiple fin structures 110 extending along a first horizontal direction (e.g., in the x-direction) and gate structure 115 traversing through the multiple fin structures 110 along a second horizontal direction (e.g., in the y-direction). In some embodiments, a crystal orientation of fin structures 110 can be the same as the crystal orientation of substrate 102.

One or more nano-sheet (NS) layers 120 can be disposed over fin structure 110. Each NS layer 120 can be wrapped by gate structure 115 to function as GAAFET 105's channel. For example, a top surface, side surfaces, and a bottom surface of each NS layer 120 can be surrounded and in physical contact with gate structure 115. Fin structure 110 and NS layer 120 can be made of materials similar to (e.g., lattice mismatch within about 5%) substrate 102. In some embodiments, a crystal orientation of NS layer 120 can be the same as the crystal orientation of fin structures 110. In some embodiments, each of fin structure 110 and NS layer 120 can be made of Si or SiGe. Each of fin structure 110 and NS layer 120 can be un-doped, doped with p-type dopants, doped with n-type dopants, or doped with intrinsic dopants. In some embodiments, fin structure 110 and NS layers 120 can be together doped with p-type dopants or together doped with n-type dopants. Although FIG. 1 shows that each GAAFET 105 includes four NS layers 120, any number of NS layers 120 can be included in each GAAFET 105.

Gate structures 115 can be a multilayered structure that wrap around each NS layer 120 to modulate GAAFET 105. Gate structures 115 can have a length Lc representing GAAFET 105's channel length. Length Lc can have any suitable horizontal (e.g., in the x-direction) dimension, such as from about 3 nm to about 200 nm. By way of example and not limitation, each gate structure 115 can include a dielectric stack formed by an interfacial dielectric layer 115a and a gate dielectric layer 115b. Further, each gate structure 115 includes a gate electrode 115c with capping layers, one or more work function metallic layers, and a metal fill not individually shown in FIG. 1 for simplicity. Gate dielectric layer 115b can include any suitable dielectric material with any suitable thickness that can provide channel modulation for GAAFET 105. In some embodiments, gate dielectric layer 115b can be made of silicon oxide or a high-k dielectric material (e.g., hafnium oxide or aluminum oxide). In some embodiments, gate dielectric layer 115b can have a thickness ranging from about 1 nm to about 5 nm. Based on the disclosure herein, other materials and thicknesses for gate dielectric layer 115b are within the scope and spirit of this disclosure. Gate electrode 115c can function as a gate terminal for GAAFET 105. Gate electrode 115c can include any suitable conductive material that provides a suitable work function to modulate GAAFET 105. In some embodiments, gate electrode 115c can be made of titanium nitride, tantalum nitride, tungsten nitride, titanium, aluminum, copper, tungsten, tantalum, copper, or nickel. Based on the disclosure herein, other materials for gate electrode 115c are within the scope and spirit of this disclosure.

S/D epitaxial structures 125 can be disposed over opposite sides (e.g., along x-direction) of each NS layer 120 to function as GAAFET 105's source and drain terminals. S/D epitaxial structures 125 can be disposed on fin structures 110. In some embodiments, S/D epitaxial structures 125 can be disposed on an isolation layer 145 on fin structures 110, such that S/D epitaxial structures 125 and fin structures 110 are electrically isolated. S/D epitaxial structure 125 can be made of an epitaxially-grown semiconductor material similar to (e.g., lattice mismatch within about 5%) NS layer 120. In some embodiments, S/D epitaxial structures 125 can be made of Si, Ge, SiGe, InGaAs, or GaAs. S/D epitaxial structures 125 can be doped with p-type dopants, n-type dopants, or intrinsic dopants. In some embodiments, S/D epitaxial structures 125 can have a different doping type from NS layer 120. In some embodiments, the n-type dopants in S/D epitaxial structure 125 can include P, As, Sb, and/or a combination thereof. In some embodiments, a crystal orientation of S/D epitaxial structure 125 can be the same as the crystal orientation of NS layer 120.

Semiconductor device 100 can further include gate spacers 135 formed between gate structure 115 and S/D epitaxial structure 125, which provide structural support during the formation of gate structures 115. In addition, gate spacers 135 provide gate structures 115 with electrical isolation and protection during the formation of S/D contacts, which are not shown in FIG. 1. Gate spacers 135 can be made of any suitable dielectric material. In some embodiments, gate spacers 135 can be made of silicon oxide, silicon nitride, or a low-k material with a dielectric constant less than about 3.9. In some embodiments, gate spacers 135 can have any suitable thickness, such as from about 5 nm to about 15 nm. Based on the disclosure herein, other materials and thicknesses for gate spacers 135 are within the scope and spirit of this disclosure.

Semiconductor device 100 can further include shallow trench isolation (STI) regions 138 configured to provide electrical isolation between fin structures 110. Also, STI regions 138 can provide electrical isolation between GAAFET 105 and neighboring active and passive elements integrated with or deposited on substrate 102. STI regions 138 can include one or more layers of dielectric material, such as a nitride layer, an oxide layer disposed on the nitride layer, and an insulating layer disposed on the nitride layer. In some embodiments, the insulating layer can include silicon oxide, silicon nitride, silicon oxynitride, fluorine-doped silicate glass (FSG), a low-k dielectric material, and/or other suitable insulating materials. Based on the disclosure herein, other dielectric materials for STI region 138 are within the scope and spirit of this disclosure.

Semiconductor device 100 can further include interlayer dielectric (ILD) layers 165 to provide electrical isolation to structural elements it surrounds or covers, such as gate structures 115 and S/D epitaxial structures 125. In some embodiments, gate spacers 135 can be formed between gate structures 115 and ILD layers 165. ILD layers 165 can include any suitable dielectric material to provide electrical insulation, such as silicon oxide, silicon dioxide, silicon oxycarbide, silicon oxynitride, silicon oxy-carbon nitride, and silicon carbonitride. ILD layers 165 can have any suitable thickness, such as from about 50 nm to about 200 nm, to provide electrical insulation. Based on the disclosure herein, other insulating materials and thicknesses for ILD layers 165 are within the scope and spirit of this disclosure.

Semiconductor device 100 can further include inner spacer structures 130 abutting (or in contact with) side surfaces of gate structures 115. Inner spacer structures 130 can separate gate structures 115 from S/D epitaxial structures 125. For example, inner spacer structures 130 can be formed at gate structures 115's opposite sides along GAAFETs 105's channel direction (e.g., along the x-direction) to separate gate structures 115 from S/D epitaxial structures 125. In some embodiments, inner spacer structures 130 can be formed between two vertically (e.g., in the z-direction) adjacent NS layers 120. In some embodiments, inner spacer structures 130 can be formed between fin structures 110 and NS layers 120. In some embodiments, inner spacer structures 130 can include a silicon-based dielectric, such as silicon nitride (SiN), silicon oxy-carbon-nitride (SiOCN), silicon carbon-nitride (SiCN), or silicon oxy-nitride (SiON). In some embodiments, inner spacer structures 130 can include a low-k material, such as a porous material and a carbon-rich silicon oxide based dielectrics.

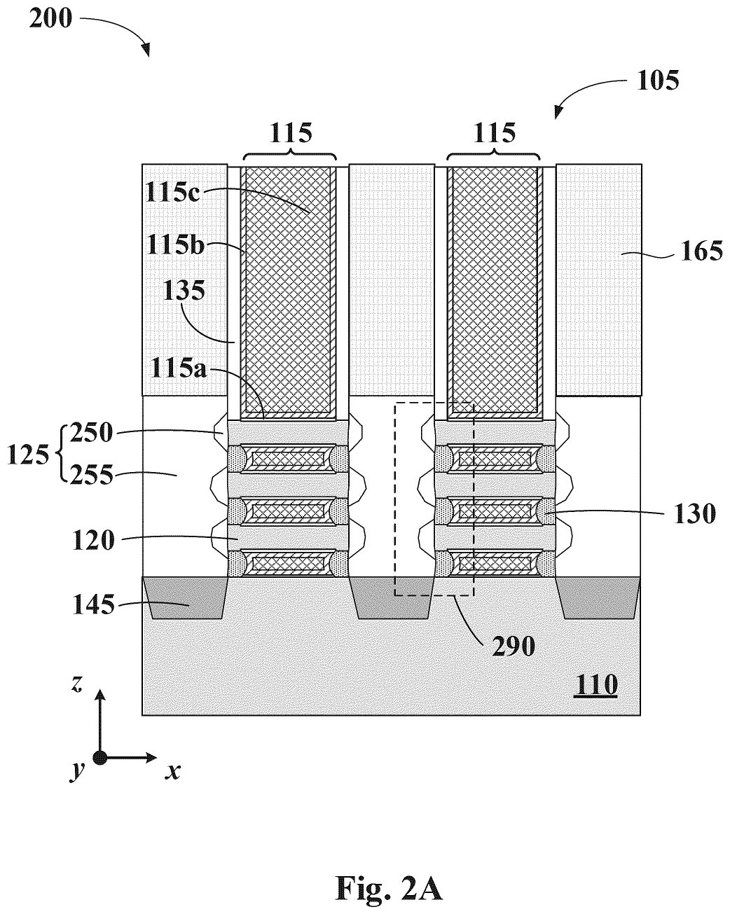

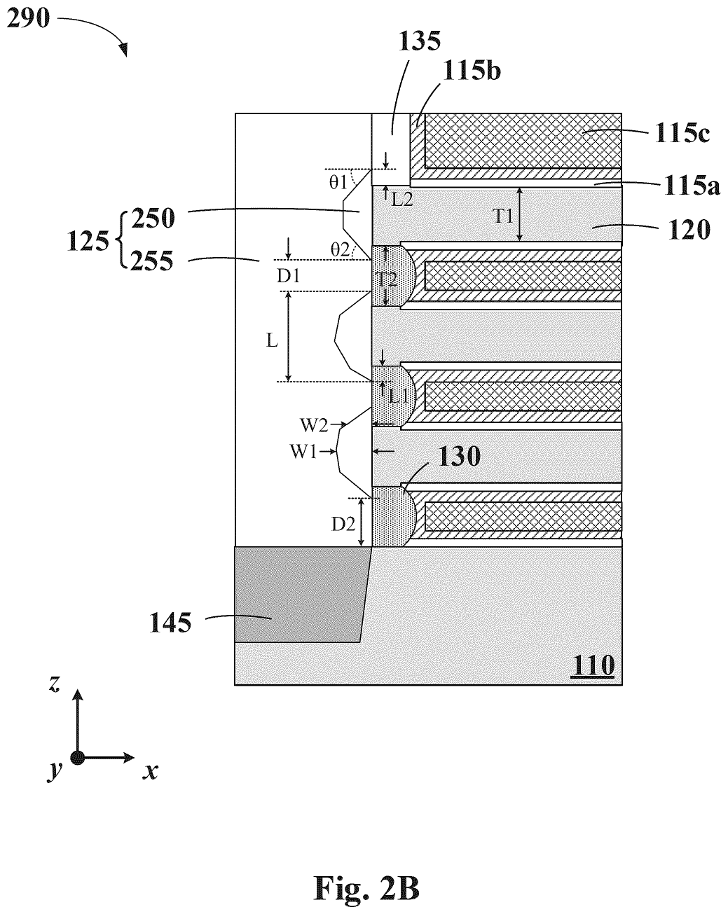

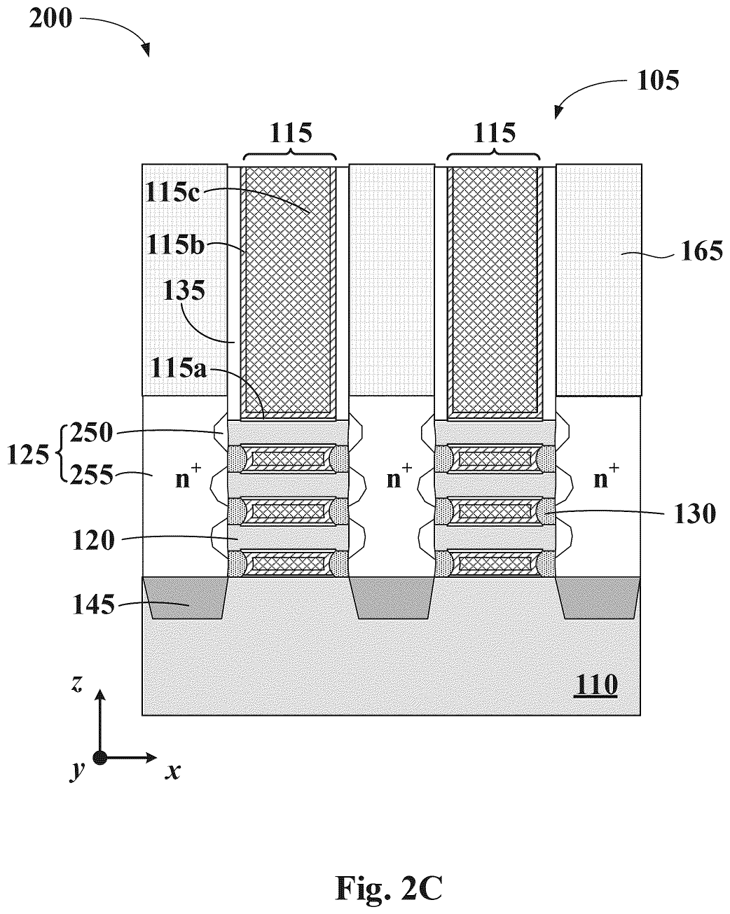

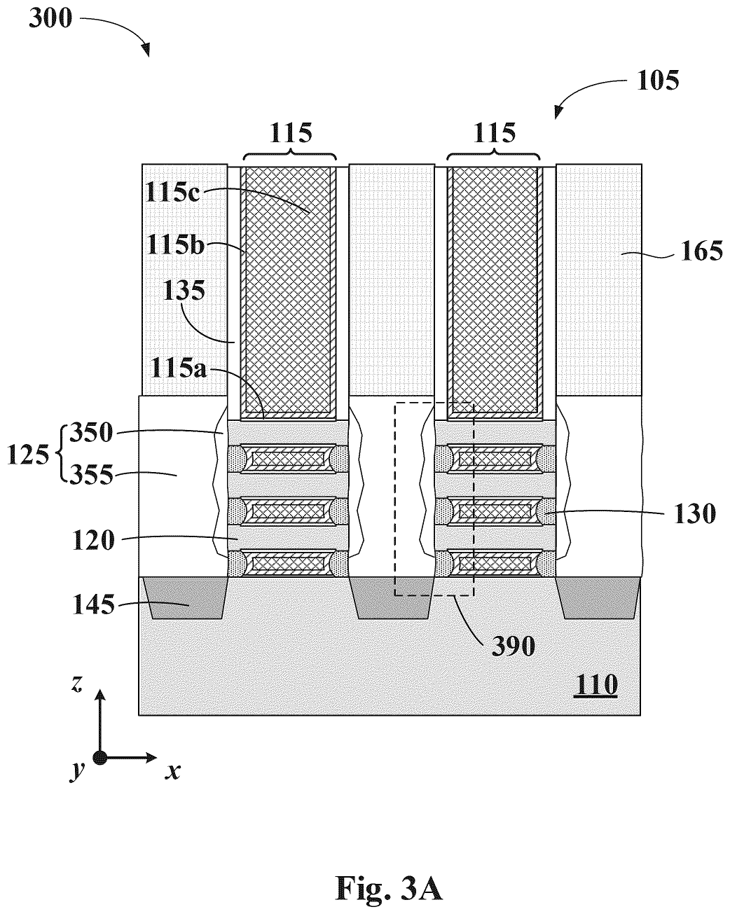

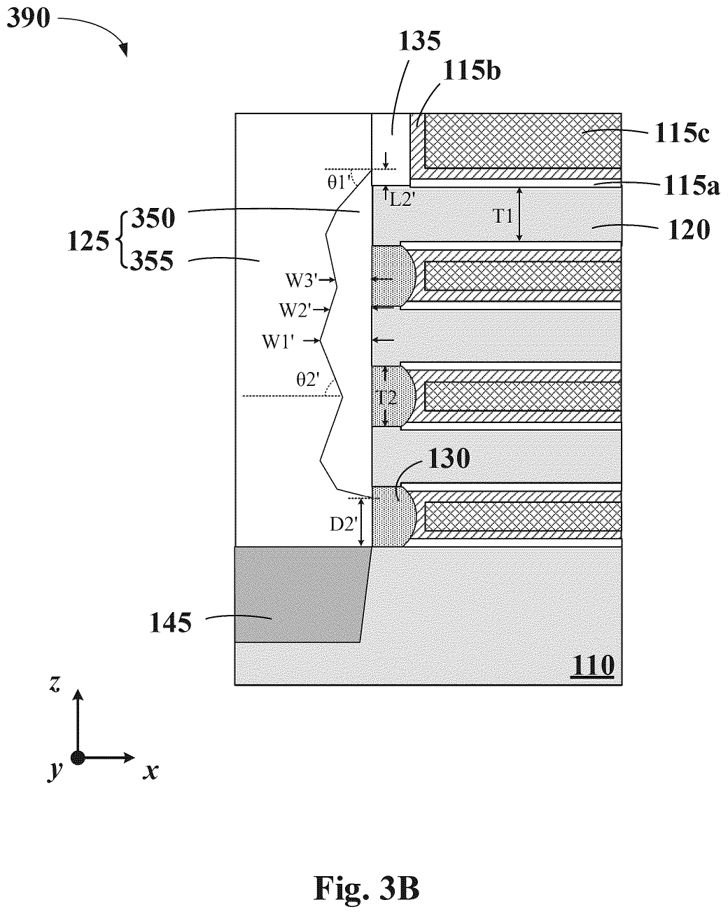

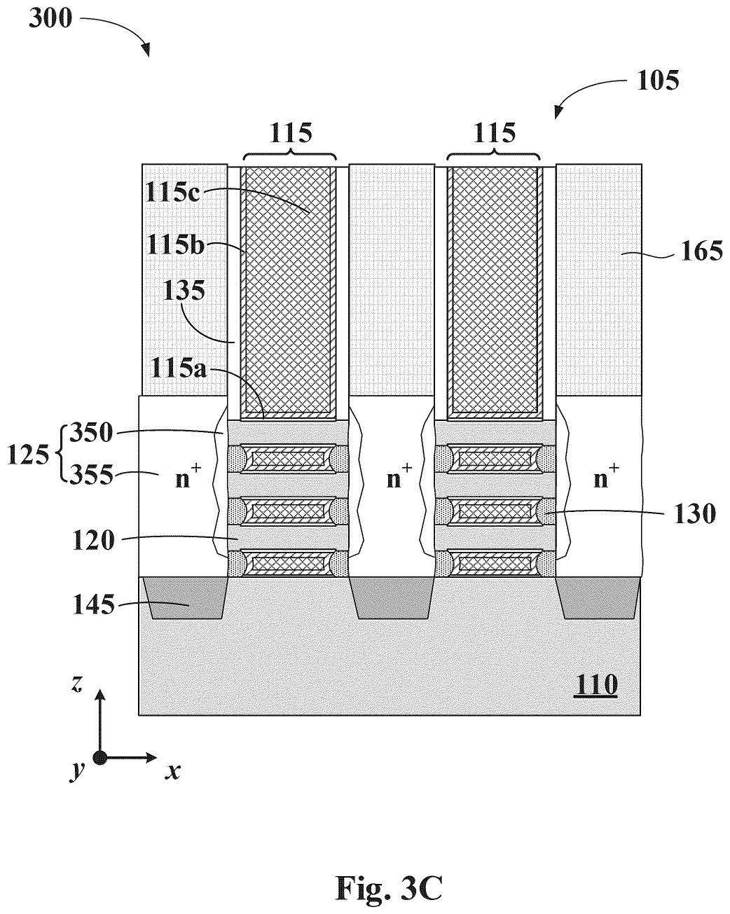

FIGS. 2A and 3A illustrate cross-sectional (e.g., along the x-z plane) views 200 and 300, respectively, of semiconductor device 100 along line B-B of FIG. 1, according to some embodiments. FIGS. 2B and 3B illustrate zoomed-in portions 290 and 390 in the cross-sectional views 200 and 300 in FIGS. 2A and 3A, respectively. FIGS. 2C and 3C illustrate embodiments of n-type nanosheet transistors having diffusion barrier structures in S/D epitaxial structures. The discussion of elements in FIG. 1 with the same annotations applies to FIGS. 2A-2C and 3A-3C, unless mentioned otherwise.

FIG. 2A illustrates an embodiment of an S/D epitaxial structure including diffusion barrier structures. Referring to FIG. 2A, each S/D epitaxial structure 125 can include low doping regions 250 and a high doping region 255. High doping region 255 is isolated (or separated) from NS layers 120 by low doping regions 250. Low doping regions 250 can have a dopant concentration less than that of high doping region 255. Low doping regions 250 can cover side surfaces of NS layers 120, preventing (or mitigating) the dopants in high doping region 255 from diffusing into NS layers 120. Low doping regions 250 can also be referred to as “diffusion barrier structures 250.” In some embodiments, high doping region 255 and low doping regions 250 can include the same semiconductor material (e.g., Si). In some embodiments, high doping region 255 and low doping regions 250 can be doped with the same type (e.g., n-type) of dopant. In some embodiments, dopants in high doping region 255 can be doped with phosphorous and have a dopant concentration between about 5×10²⁰ cm⁻³ and about 5×10²¹ cm 3. In some embodiments, dopants in low doping regions 250 can be doped with phosphorous, arsenic, antimony, and/or a combination thereof and can have a dopant concentration between about 1×10²⁰ cm⁻³ and about 2×10²¹ cm⁻³.

FIG. 2B illustrates the zoomed-in portion 290 in FIG. 2A. In some embodiments, a diffusion barrier structure 250 can extend vertically (e.g., along the z-axis) beyond edges of an interface between diffusion barrier structure 250 and an NS layer 120. In some embodiments, as shown in FIG. 2B, a vertical length L of diffusion barrier structure 250 can be greater than a thickness T1 of NS layer 120. In some embodiments, a side surface of diffusion barrier structure 250 can extend over an inner spacer structure 130 adjacent to NS layer 120. In some embodiments, diffusion barrier structure 250 can be in direct contact with inner spacer structure 130. For example, as shown in FIG. 2B, an interface between diffusion barrier structure 250 and inner spacer structure 130 can have a length L1 along the z-axis. In some embodiments, length L1 can be less than about 4 nm. For example, length L1 can be about 0.5 nm, about 1 nm, about 2 nm, or about 3 nm.

In some embodiments, a diffusion barrier structure 250 in contact with a topmost NS layer 120 can extend vertically over a gate spacer 135 on the topmost NS layer 120. In some embodiments, diffusion barrier structure 250 can be in direct contact with a side surface of gate spacer 135. For example, as shown in FIG. 2B, an interface between diffusion barrier structures 250 and gate spacer 135 can have a length L2 along the z-axis. In some embodiments, length L2 can be less than about 4 nm. For example, length L2 can be about 0.5 nm, about 1 nm, about 2 nm, or about 3 nm. In some embodiments, high doping region 255 can be in contact with gate spacer 135, and an interface between high doping region 255 and gate spacer 135 is above the interface between diffusion barrier structures 250 and gate spacer 135.

In some embodiments, high doping region 255 can be in contact with an inner spacer structure 130. In some embodiments, a side surface of inner spacer structure 130 can be in contact with side surfaces of two adjacent diffusion barrier structures 250 and a side surface of high doping region 255. In some embodiments, a vertical distance D1 between the two adjacent diffusion barrier structures 250 can be less than the vertical thickness T2 of inner spacer structure 130. In some embodiments, vertical distance D1 can be between about 1 nm and about 4 nm. For example, vertical distance D1 can be about 1 nm, about 2 nm, about 3 nm, or about 4 nm. The coverage of diffusion barrier structures 250 over inner spacer structure 130 can prevent (or mitigate) dopants in high doping region 255 from diffusing through inner spacer structure 130 into NS layers 120.

In some embodiments, a vertical distance D2 between a bottom most diffusion barrier structure 250 and fin structure 110 can be less than vertical thickness T2. In some embodiments, vertical distance D2 can be between about 1 nm and about 4 nm. For example, vertical distance D2 can be about 1 nm, about 2 nm, about 3 nm, or about 4 nm.

In some embodiments, each diffusion barrier structure 250 can have uneven widths along a horizontal direction (e.g., along the x-axis). For example, as shown in FIG. 2B, diffusion barrier structure 250 can have a width W1 and a width W2, with width W1 measured proximate to the middle point of the interface between diffusion barrier structure 250 and NS layer 120 and width W2 measured proximate to the edge of the interface between diffusion barrier structure 250 and NS layer 120. In some embodiments, width W1 can be greater than width W2. In some embodiments, width W1 can be between about 1 nm and about 8 nm. For example, width W1 can be about 1 nm, about 2 nm, about 3 nm, about 4 nm, about 5 nm, about 6 nm, about 7 nm, or about 8 nm. In some embodiments, width W2 can be between about 1 nm and about 5 nm. For example, width W2 can be about 1 nm, about 2 nm, about 3 nm, about 4 nm, or about 5 nm.

In some embodiments, each diffusion barrier structure 250 can include slanted surfaces. For example, as shown in FIG. 2B, an angle θ1 between a horizontal plane (e.g., the x-y plane) and a surface in connection to a topmost point of diffusion barrier structure 250 can be between about 0° and about 90°. For example, 01 can be about 45°, about 60°, about 70°, about 80°, and about 85°. Also as shown in FIG. 2B, an angle θ2 between the horizontal plane and a surface in connection to a bottommost point of diffusion barrier structure 250 can be between about 0° and about 90°. For example, 02 can be about 45°, about 60°, about 70°, about 80°, or about 85°. In some embodiments, angles θ1 and θ2 can be less than arctan (T1/2(W1−W2)).

FIG. 2C illustrates an embodiment of n-type nanosheet transistors having diffusion barrier structures over inner spacers. Referring to FIG. 2C, each S/D epitaxial structure 125 can include low doping regions 250 and high doping regions 255. High doping regions 255 can be heavily doped (n) with n-type donors, such as phosphorous. For example, a dopant concentration of high doping regions 255 can be between about 5×10²⁰ cm⁻³ and about 5×10²¹ cm⁻³. Low doping regions 250 can have a doping concentration less than high doping regions 255 and can be the diffusion barrier structures preventing (or mitigating) the dopants in high doping regions 255 from diffusing into NS layers 120. For example, a dopant concentration of low doping regions 250 can be between about 1×10²⁰ cm⁻³ and about 2×10²¹ cm⁻³. Dopants in low doping regions 250 can be P, As, Sb, or a combination thereof. In some embodiments, a side surface of low doping regions 250 can extend over inner spacer structure 130 adjacent to NS layer 120.

FIG. 3A illustrates another embodiment of an S/D epitaxial structure having diffusion barrier structures. Referring to FIG. 3A, each S/D epitaxial structure 125 can include low doping regions 350 and a high doping region 355. High doping region 355 is isolated (or separated) from NS layers 120 by low doping regions 350. The discussion of elements in FIG. 2A applies to those with the same annotations in FIG. 3A. The discussion of low doping regions 250 and high doping regions 255 in FIG. 2A also applies to low doping regions 350 and high doping regions 355, respectively, unless mentioned otherwise. Low doping regions 350 can also be referred to as “diffusion barrier structures 350.” In some embodiments, portions of low doping regions 350 in contact with adjacent NS layers can extend over inner spacer structures 130 and merge with each other, as shown in FIG. 3A.

FIG. 3B illustrates the zoomed-in portion 390 in FIG. 3A. In some embodiments, diffusion barrier structure 350 can extend across a side surface of an inner spacer structure 130. In some embodiments, the entire surface of inner spacer structure 130 can be in direct contact with diffusion barrier structure 350. In some embodiments, a diffusion barrier structure 350 can extend vertically across multiple NS layers 120 and/or multiple inner spacer structures 130. In some embodiments, diffusion barrier structure 350 can extend vertically over gate spacer 135. In some embodiments, diffusion barrier structure 350 can be in direct contact with a side surface of gate spacer 135. For example, as shown in FIG. 3B, an interface between diffusion barrier structures 350 and gate spacer 135 can have a length L2′ along the z-axis. In some embodiments, length L2′ can be less than about 4 nm. For example, length L2′ can be about 0.5 nm, about 1 nm, about 2 nm, or about 3 nm. In some embodiments, a vertical distance D2′ between the diffusion barrier structure 350 and fin structure 110 can be less than vertical thickness T2. In some embodiments, vertical distance D2′ can be between about 1 nm and about 4 nm. For example, vertical distance D2′ can be about 1 nm, about 2 nm, about 3 nm, or about 4 nm. The coverage of diffusion barrier structure 350 over inner spacer structures 130 can prevent (or mitigate) dopants in high doping region 355 from diffusing through inner spacer structure 130 into NS layers 120.

In some embodiments, diffusion barrier structure 350 can have uneven widths along a horizontal direction (e.g., along the x-axis). In some embodiments, diffusion barrier structure 350 can have a width W1′, a width W2′, and a width W3′, with width W1′ measured proximate to the middle point of the interface between diffusion barrier structure 350 and NS layer 120, width W2′ measured proximate to the edge of the interface between diffusion barrier structure 350 and NS layer 120, and width W3′ of measured proximate to the middle point of the interface between diffusion barrier structure 350 and inner spacer structure 130. In some embodiments, width W1′ can be greater than width W2′, which is greater than width W3′. In some embodiments, width W1′ can be between about 1 nm and about 8 nm. For example, width W1′ can be about 1 nm, about 2 nm, about 3 nm, about 4 nm, about 5 nm, about 6 nm, about 7 nm, or about 8 nm. In some embodiments, width W2′ can be between about 1 nm and about 5 nm. For example, width W2′ can be about 1 nm, about 2 nm, about 3 nm, about 4 nm, or about 5 nm. In some embodiments, width W3′ can be between about 1 nm and about 3 nm. For example, width W3′ can be about 1 nm, about 2 nm, or about 3 nm.

In some embodiments, diffusion barrier structure 350 can include slanted surfaces. For example, as shown in FIG. 3B, an angle θ1′ between a horizontal plane (e.g., the x-y plane) and a surface in connection to a topmost point of diffusion barrier structure 350 can be between about 0° and about 90°. For example, θ1′ can be about 45°, about 60°, about 70°, about 80°, or about 85°. Also as shown in FIG. 3B, an angle θ2′ between the horizontal plane and a surface in connection to a narrowest portion of diffusion barrier structure 250 can be between about 0° and about 90°. For example, θ2′ can be about 45°, about 60°, about 70°, about 80°, or about 85°. In some embodiments, angles θ1′ and θ2′ can be less than arctan (T1/2(W1′−W2′)).

FIG. 3C illustrates an embodiment of n-type nanosheet transistors having diffusion barrier structures over inner spacers. Referring to FIG. 3C, each S/D epitaxial structure 125 can include low doping regions 350 and high doping regions 355. High doping regions 355 can be heavily doped (n) with n-type donors, such as phosphorous. For example, a dopant concentration of high doping regions 355 can be between about 5×10²⁰ cm⁻³ and about 5×10²¹ cm⁻³. Low doping regions 350 can have a doping concentration less than high doping regions 355 and can be the diffusion barrier structures preventing (or mitigating) the dopants in high doping regions 355 from diffusing into NS layers 120. For example, a dopant concentration of low doping regions 350 can be between about 1×10²⁰ cm⁻³ and about 2×10²¹ cm⁻³. Dopants in low doping regions 350 can be P, As, Sb, or a combination thereof. In some embodiments, a side surface of low doping regions 350 can cover inner spacer structure 130 adjacent to NS layer 120.

Although the two embodiments of diffusion barrier structures presented in FIGS. 2A-3C are different, it is to be understood by those skilled in relevant art(s) that the different features of these embodiments can be included in a single embodiment. For example, an S/D epitaxial structure can include both a diffusion barrier structure 250 and a diffusion barrier structure 350.

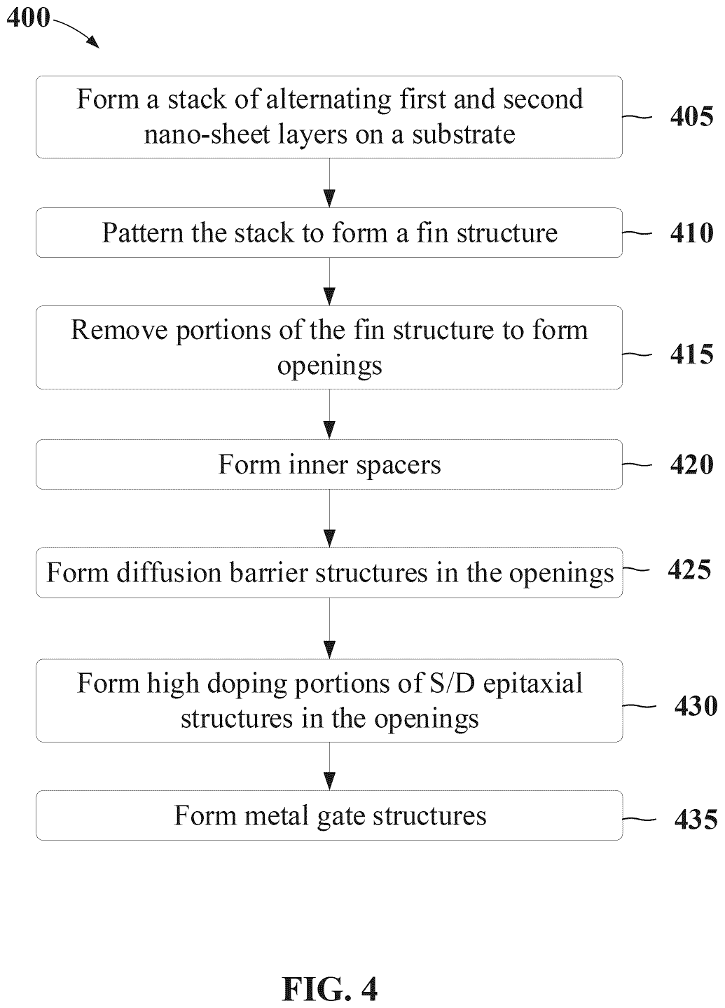

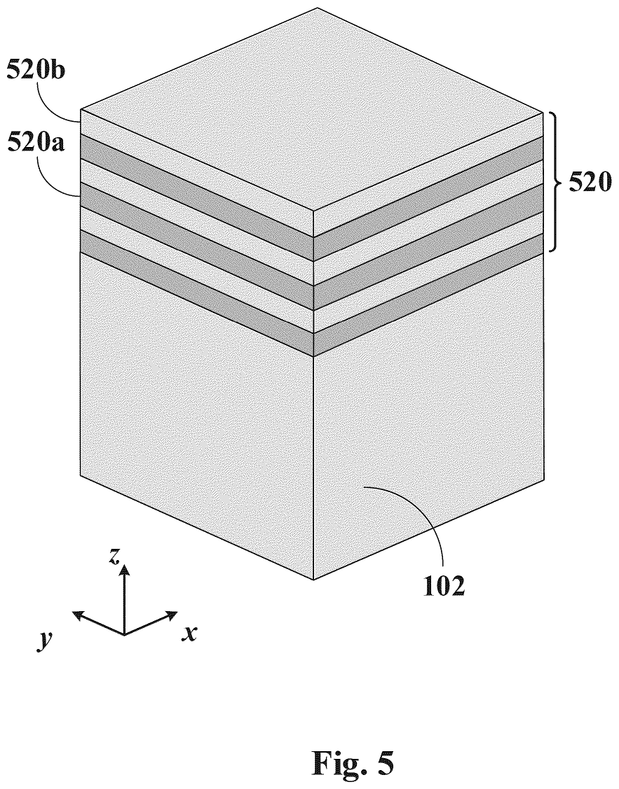

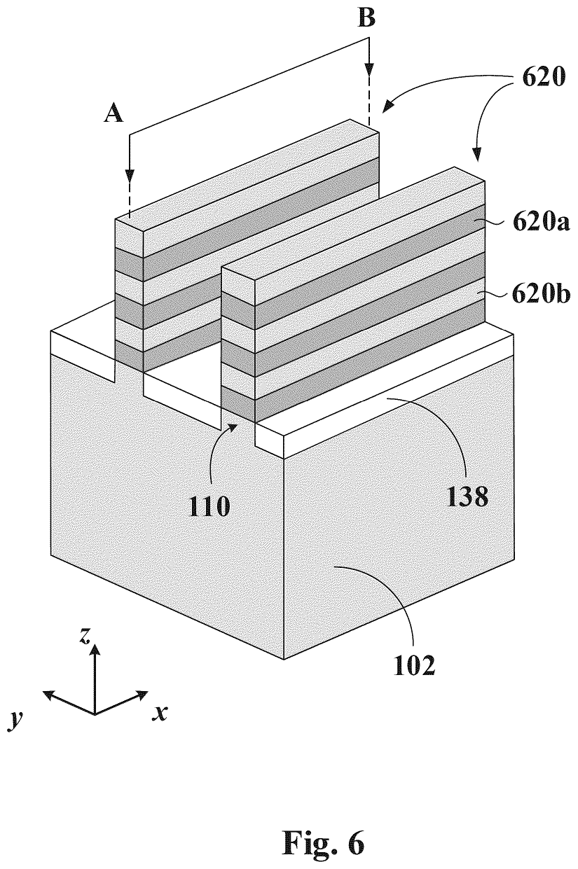

According to some embodiments, FIG. 4 illustrates a flowchart of a fabrication method 400 for the formation of GAAFETs 105 shown in FIGS. 1-3B. This disclosure is not limited to this operational description and additional operations may be performed. Other fabrication operations can be performed between the various operations of method 400 and are omitted merely for clarity. Moreover, not all operations may be needed to perform the disclosure provided herein. Additionally, some of the operations may be performed simultaneously, or in a different order than the ones shown in FIG. 4. In some embodiments, one or more other operations may be performed in addition to or in place of the presently described operations. For illustrative purposes, method 400 is described with reference to the structures shown in FIGS. 5-14B.

In referring to FIG. 4, method 400 begins with operation 405 and the process of forming a stack of alternating first and second NS layers on a substrate (e.g., substrate 102). FIG. 5 is an isometric view of substrate 102 after operation 405 and the formation of a stack 520 of alternating first and second NS layers 520a and 520b. In some embodiments, first and second NS layers 520a and 520b are formed on an exposed top surface of substrate 102. In some embodiments, first NS layers 520a are sacrificial NS layers subject to subsequent removal and second NS layers 520b correspond to NS layers 120 shown in FIG. 1. In some embodiments, the material of first NS layers 520a in stack 520 is selected so that first NS layers 520a can be selectively removed via etching from stack 520 without removing second NS layers 520b. For example, second NS layers 520b can be Si NS layers and first NS layers 520a can be SiGe NS layers.

First and second NS layers 520a and 520b can be grown with any suitable method. For example, first and second NS layers 520a and 520b can be grown with a CVD process with precursor gases, like silane (SiH₄), disilane (Si₂H₆), dichlorosilane (SiH₂Cl₂), trichlorosilane (SiHCl₃), germane (GeH₄), digermane (Ge₂H₆), other suitable gases, or combinations thereof. In some embodiments, first NS layers 520a can include Ge with a concentration between about 20% and about 30%, while second NS layers 120 are substantially germanium-free—e.g., have a Ge concentration less than about 1%. In some embodiments, second NS layers 520b, which correspond to NS layers 120 in FIG. 1, form the channel region of GAAFET 105 and can be lightly doped or intrinsic (e.g., un-doped). If lightly doped, the doping level of second NS layers 520b is less than about 10¹³ atoms/cm³. First and second NS layers 520a and 520b can be sequentially deposited without a vacuum break (e.g., in-situ) to avoid the formation of any intervening layers. In some embodiments, first NS layers 520a can be doped to increase their etching selectivity compared to second NS layers 520b in a subsequent etching operation.

In some embodiments, a thickness of first NS layers 520a controls the spacing between every other second NS layer 520b in stack 520. The thickness of first and second NS layers 520a and 520b can range, for example, from about 3 nm to about 15 nm. Since first and second NS layers 520a and 520b are grown individually, the thickness of each NS layer can be adjusted independently based, for example, on the deposition time. In some embodiments, additional or fewer number of first and second NS layers 520a and 520b can be formed in stack 520. In some embodiments, a total number of NS layers can be 2n, where n is the number of first NS layers 520a or the number of second NS layers 520b in stack 520.

In referring to FIG. 4, method 400 continues with operation 410 and the process of patterning stack 520 to form fin structures. In some embodiments, stack 520 is patterned to form fin structures with a width along the y-direction and a length along the x-direction. The fin structures can be formed by patterning with any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over stack 520 and patterned using a photolithography process. Spacers are formed alongside the patterned sacrificial layer using a self-aligned process. The sacrificial layer is then removed, and the remaining spacers may then be used as masking structures to pattern the fin structures.

By way of example and not limitation, FIG. 6 is an isometric view of fin structures 620 formed from stack 520 with the aforementioned patterning process. In some embodiments, fin structures 620 can be formed by etching first and second NS layers 520a and 520b into first and second NS layers 620a and 620b. In some embodiments, the aforementioned patterning process does not terminate on the top surface of substrate 102 but continues to etch a top portion substrate 102 to form fin structures 110 from substrate 105 under fin structures 620. Since fin structures 620 and fin structures 110 are formed with the same patterning process, fin structures 620 and fin structures 110 are substantially aligned to each other. For example, sidewall surfaces of fin structures 620 in the x-z plane and y-z plane are substantially aligned to respective sidewall surfaces of fin structures 110 as shown in FIG. 6.

Additional fin structures, like fin structures 620, can be formed on substrate 102 in the same or different area of substrate 102. These additional fin structures are not shown in FIG. 6 for simplicity. By way of example and not limitation, each fin structure 620 has a width along the y-direction between about 15 nm and about 150 nm.

In some embodiments, NS layers 620a and 620b are referred to as “nano-sheets” when their width along the y-direction is substantially different from their height along z-direction—for example, when their width is larger/narrower than their height. In some embodiments, NS layers 620a and 620b can also be referred to as “nano-wires” when their width along the y-direction is equal to their height along z-direction. In some embodiments, NS layers 620a and 620b are deposited as nano-sheets and subsequently patterned to form nano-wires with equal height and width. By way of example and not limitation, NS layers 620a and 620b will be described in the context of nano-sheets (NS) layers. Based on the disclosure herein, nano-wires (NW) are within the spirit and the scope of this disclosure. Further, for example purposes and without limiting the scope of this disclosure, first and second NS layers 620a and 620b in method 400 will be described in the context of SiGe and Si NS layers, respectively.

In some embodiments, after the formation of fin structures 620, STI regions 138 can be formed on etched or recessed portions of substrate 102 to cover sidewall surfaces of fin structures 110. In some embodiments, STI regions 138 can electrically isolate fin structures 110 and include one or more silicon oxide based dielectrics. By way of example and not limitation, STI regions 138 can be formed as follows. An isolation structure material (e.g., a silicon oxide based dielectric) is blanket deposited over fin structures 620 and substrate 102. The as-deposited isolation structure material is planarized (e.g., with a chemical mechanical polishing (CMP) process) so that the top surface of the isolation structure material is substantially coplanar with the top surface of fin structures 620. The planarized isolation structure material is subsequently etched back so that the resulting STI regions 138 has a height substantially similar to fin structures 110, as shown in FIG. 6. In some embodiments, fin structures 620 protrudes from STI regions 138 so that STI regions 138 does not cover sidewall portion of fin structures 620 as shown in FIG. 6. This is intentional and facilitates the formation of GAAFETs 105 shown in FIG. 1.

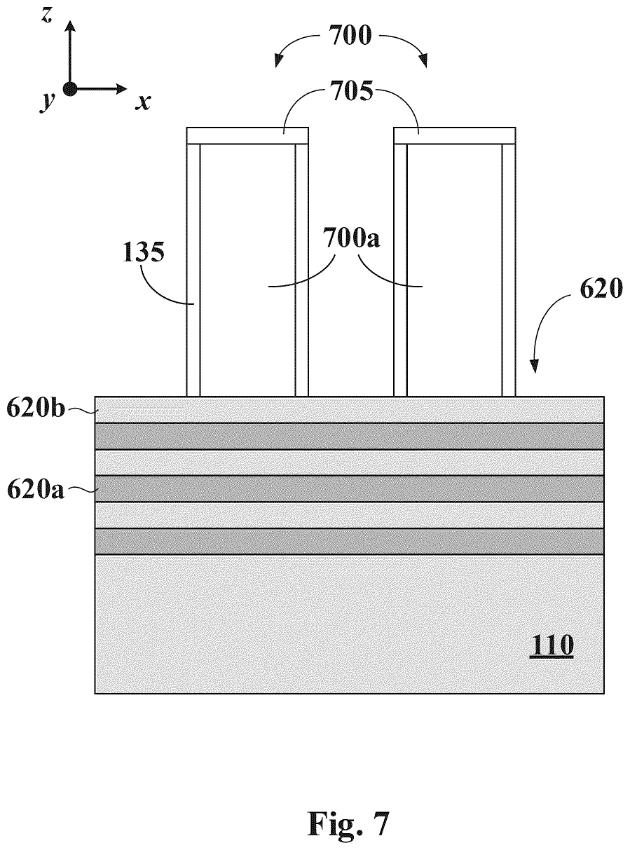

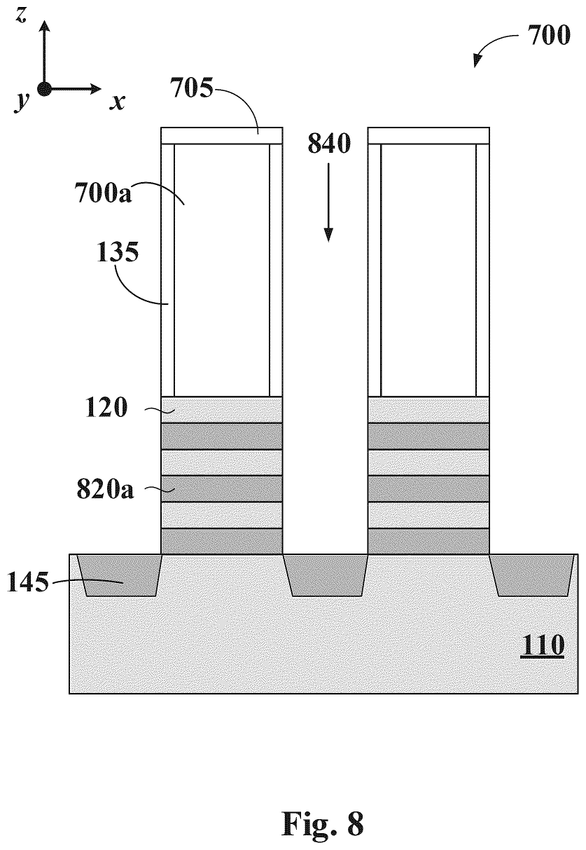

Method 400 continues with operation 415 and the process of removing portions of the fin structures to form openings in the fin structures, including (i) forming sacrificial gate structures 700, as described with reference to FIG. 7 and (ii) removing the portions of fin structure 620 exposed by sacrificial gate structures 700, as described with reference to FIG. 8.

In some embodiments, sacrificial gate structures 700 are formed with their length along the y-direction—e.g., perpendicular to fin structures 620 shown in the isometric view of FIG. 6—and their width along the x-direction. By way of example and not limitation, FIG. 7 is a cross-sectional view of FIG. 6 along cut-line AB. FIG. 7 shows sacrificial gate structures 700 formed on portions of fin structures 620. Because FIG. 7 is a cross-sectional view, as opposed to an isometric view, portions of sacrificial gate structures 700 covering sidewall portions of fin structures 620 are not shown. Further, in the cross-sectional view of FIG. 7, only one of fin structures 620 from FIG. 6 is shown. In some embodiments, portions of sacrificial gate structures 700 are formed between fin structures 620 and on STI regions 138 shown in FIG. 6.

In some embodiments, sacrificial gate structures 700 cover top and sidewall portions of fin structures 620. In some embodiments, sacrificial gate structures 700 are subsequently replaced by gate structures 115 shown in FIG. 1 during a gate replacement process. Sacrificial gate structures 700 can include a sacrificial gate electrode 700a formed on a sacrificial gate dielectric not shown in FIG. 7 for simplicity. Sacrificial gate structures 700 can also include capping layers 705 formed on top surfaces of sacrificial gate structures 700. In some embodiments, capping layers 705 can protect sacrificial gate electrode 700a from subsequent etching operations. At this fabrication stage, gate spacers 135 can be formed on side surfaces of sacrificial gate structures 700. As discussed above, gate spacers 135 are not removed during the gate replacement process; instead, gate spacers 135 facilitate the formation of gate structures 115.

By way of example and not limitation, sacrificial gate structures 700 can be formed by depositing and patterning sacrificial gate electrode 700a over fin structures 620. In some embodiments, sacrificial gate structures 700 are formed over multiple fin structures 620. As shown in FIG. 7, portions of fin structures 620 are not covered by sacrificial gate structures 700. This is because the width of sacrificial gate structures 700 is narrower than the length of fin structures 620 along the x-direction. In some embodiments, sacrificial gate structures 700 are used as masking structures in subsequent etching operations to define the channel region of GAAFETs 105 shown in FIG. 1. For this reason, the lateral dimensions (e.g., the width and length) of sacrificial gate structures 700 and gate structures 115 are substantially similar.

In referring to FIG. 8, portions of fin structures 620 not covered by sacrificial gate structures 700 can be removed. In some embodiments, the removal process involves a dry etching process, a wet etching process, or combinations thereof. The removal process is selective towards first NS layers 620a and second NS layers 620b, shaping them into first NS layers 820a and NS layers 120, respectively. In some embodiments, the dry etching process includes etchants having an oxygen-containing gas, a fluorine-containing gas (e.g., carbon tetrafluoride (CF₄), sulfur hexafluoride (SF₆), difluoromethane (CH₂F₂), trifluoromethane (CHF₃), and/or hexafluoroethane (C₂F₆)); a chlorine-containing gas (e.g., chlorine (Cl₂), chloroform (CHCl₃), carbon tetrachloride (CCl₄), and/or boron trichloride (BCl₃)); a bromine-containing gas (e.g., hydrogen bromide (HBr) and/or bromoform (CHBr₃)); an iodine-containing gas; other suitable etching gases and/or plasmas; or combinations thereof. The wet etching chemistry can include diluted hydrofluoric acid (DHF), potassium hydroxide (KOH) solution, ammonia; a solution containing hydrofluoric acid (HF), nitric acid (HNO₃), acetic acid (CH₃COOH); or combinations thereof.

In some embodiments, the etchants of the aforementioned etching process do not substantially etch sacrificial gate structures 700—which is protected by capping layers 705 and gate spacers 135—and STI regions 138 shown in FIG. 6. This is because capping layers 705, gate spacers 135, and STI regions 138 include materials with a low etching selectivity, such as a silicon nitride based material (e.g., silicon nitride, silicon carbon nitride, and silicon carbon oxy-nitride) or silicon oxide based materials. In some embodiments, STI regions 138 shown in FIG. 6 is used as an etch stop layer for the etching process described above.

Because of operation 415, openings 840 are formed in each fin structure 620 as shown in FIG. 8. Openings 840 divides each fin structure 620 into separate portions, with each portion covered by a sacrificial gate structure 700. In some embodiments, the removal process in operation 415 can further include removing portions of fin structure 110 uncovered by remaining portions of fin structure 620. Removing the portions of fin structure 110 can include etching the portions of fin structure 110 in a similar way as etching the portions of fin structures 620 not covered by sacrificial gate structures 700. In some embodiments, isolation layer 145 can be deposited on the bottom surface of opening 840 to fill the space left by the removal of the portions of fin structure 110.

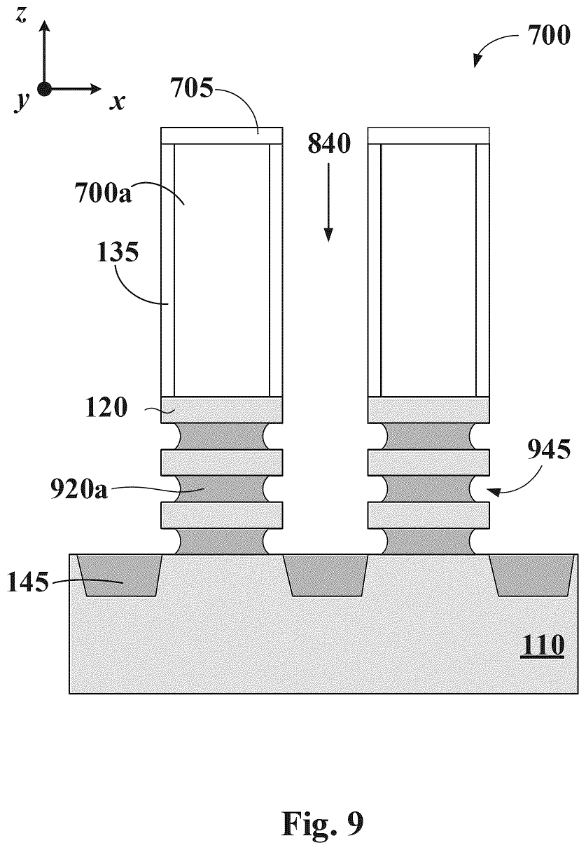

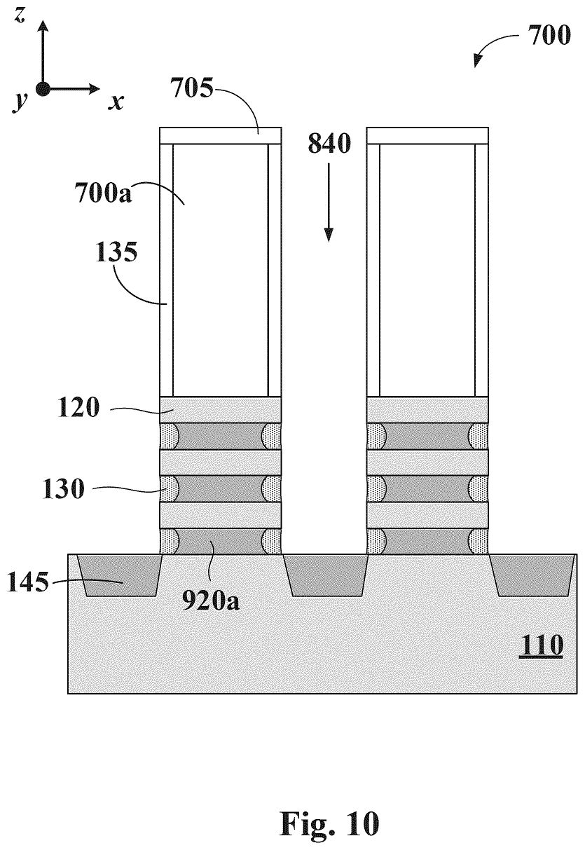

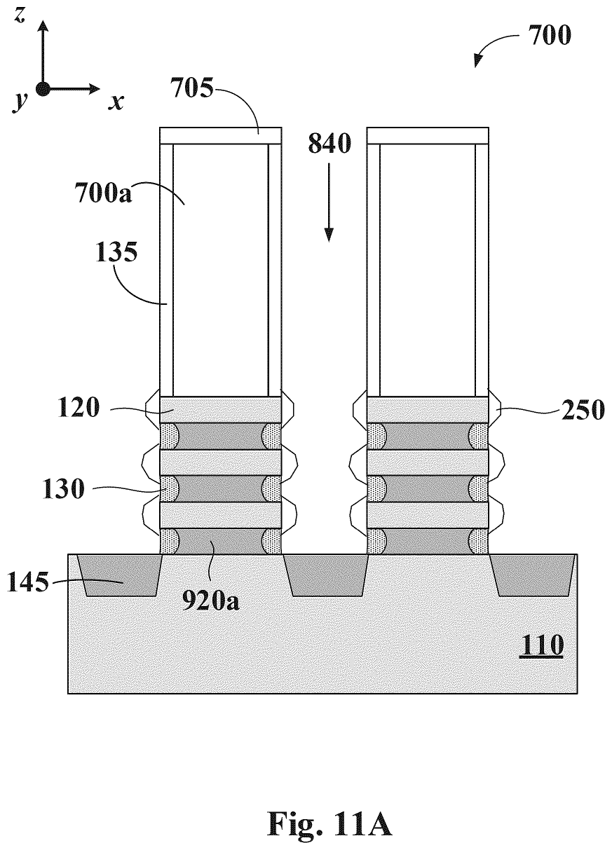

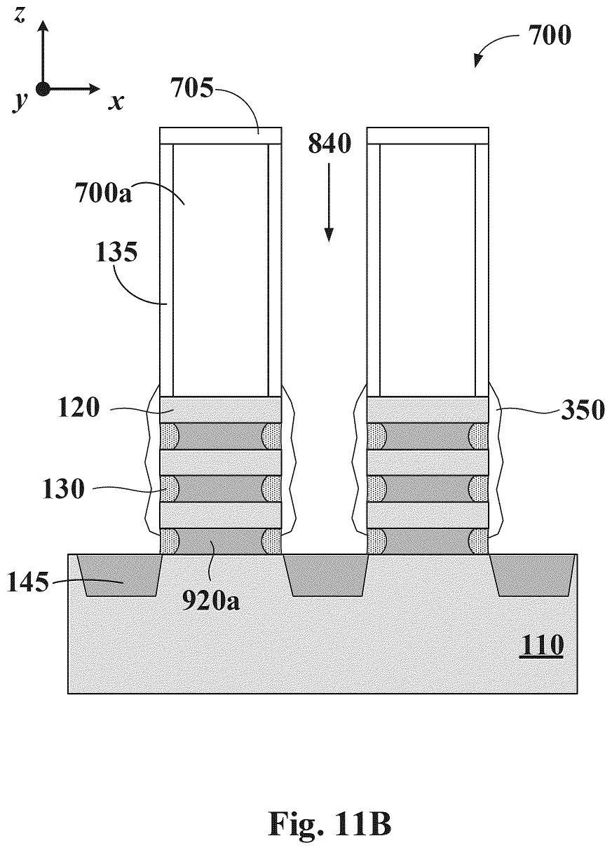

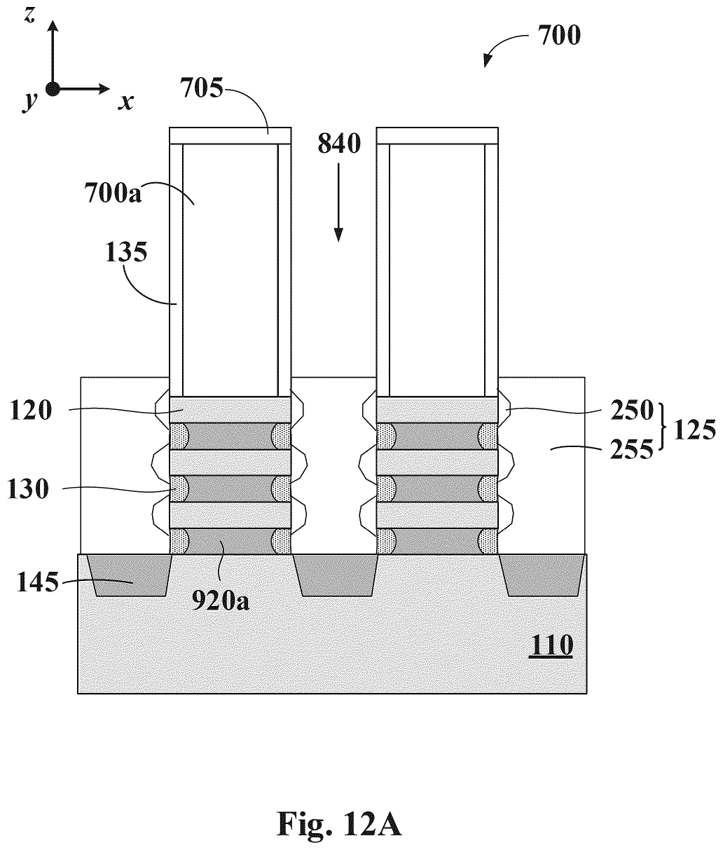

In referring to FIG. 4, method 400 continues with operation 420 and the process of forming inner spacers. The process of forming inner spacers can include (i) selectively etching edge portions of first NS layers 820a to form recess structures 945, as described with reference to FIG. 9 and (ii) depositing a dielectric material to fill the recess structures, as described with reference to FIG. 10. According to some embodiments, FIG. 9 shows the structure of FIG. 8 after exposed edges of first NS layers 820a are laterally etched (e.g., recessed) along the x-direction and turned into first NS layers 920a. According to some embodiments, exposed edges of first NS layers 820a are recessed (e.g., partially etched) by an amount that ranges from about 3 nm to about 10 nm along the x-direction as shown in FIG. 9 to form recesses structures 945.

In some embodiments, the selective etching of first NS layers 820a can be achieved with a dry etching process selective towards SiGe. For example, halogen-based chemistries exhibit a high etching selectivity towards Ge and a low etching selectivity towards Si. Therefore, halogen gases etch Ge-containing layers, such as first NS layers 820a, at a higher etching rate than substantially Ge-free layers like NS layers 120. In some embodiments, the halogen-based chemistries include fluorine-based and/or chlorine-based gasses. Alternatively, a wet etching chemistry with high selectivity towards SiGe can be used. By way of example and not limitation, a wet etching chemistry may include a mixture of sulfuric acid (H₂SO₄) and hydrogen peroxide (H₂O₂) (SPM), or a mixture of ammonia hydroxide with H₂O₂ and water (APM). The aforementioned etching processes are timed so that the desired amount of SiGe is removed.

In some embodiments, first NS layers 820a with a higher Ge atomic concentration have a higher etching rate than NS layers 120 with a lower or zero Ge atomic concentration. Therefore, the etching rate of the aforementioned etching processes can be adjusted by modulating the Ge atomic concentration (e.g., the Ge content) in first NS layers 820a. As discussed above, the Ge content in first NS layers 820a can range between about 20% and about 30%. A SiGe nano-sheet layer with about 20% Ge can be etched slower than a SiGe nano-sheet layer with about 30% Ge. Consequently, the Ge concentration can be adjusted accordingly to achieve the desired etching rate and selectivity between first NS layers 820a and NS layers 120.

In referring to FIG. 10, inner spacer structures 130 can be formed in recessed structures 945. In some embodiments, forming inner spacer structures 130 can include (i) blanket depositing a dielectric layer with a thickness between about 2 nm and about 7 nm over the entire structure of FIG. 9 and (ii) removing the portion of the dielectric layer outside recess structures 945 as shown in FIG. 9, leaving inner spacer structures 130 behind filling recessed structures 945.

In referring to FIGS. 4, method 400 continues with operation 425 and the process of forming diffusion barrier structures in the opening. As described with reference to FIGS. 11A and 11B, respectively, diffusion barrier structures 250 and 350 can be epitaxially grown on exposed side surfaces of NS layers 120.

In some embodiments, as described with reference to FIG. 11A, diffusion barrier structures 250 can be epitaxially grown with a CVD process similar to the one used in operation 405 to form first and second NS layers 520a and 520b, as described with reference to FIG. 5. In some embodiments, diffusion barrier structures 250 can be epitaxially grown using a plasma-enhanced CVD (PECVD) process. In some embodiments, precursor gases (e.g., SiH₄, SiH₂Cl₂, SiHCl₃, and/or a combination thereof) can be used to epitaxially grow a semiconductor material (e.g., Si) having a crystalline structure on side surfaces of NS layers 120. In some embodiments, flowrates of the precursor gases can be controlled. For example, a flowrate of a SiH₄ precursor gas can be between about 10 sccm to about 150 sccm, a flowrate of a SiH₂Cl₂ precursor gas can be between about 200 sccm to about 900 sccm, and a flowrate of a SiHCl₃ precursor gas can be between about 200 sccm to about 900 sccm. In some embodiments, etching gases (e.g., hydrogen chloride (HCl)) can be used to selectively remove the semiconductor material with an amorphous structure formed on dielectric surfaces (e.g., side surfaces of inner spacer structure 130 or gate spacer 135). In some embodiments, flowrates of the etching gases can be controlled. For example, a flowrate of a HCl etching gas can be between about 0 sccm to about 600 sccm. Removing the semiconductor material with the amorphous structure can ensure that the crystal structure of diffusion barrier structures 250 is crystalline. In some embodiments, dopant precursor gases, such as phosphanes (PH₃), arsanes (AsH₃), stibane (SbH₃), and/or a combination thereof can be used in the CVD process or the PECVD process to dope diffusion barrier structures 250. In some embodiments, flowrates of the dopant precursor gases can be controlled. For example, a flowrate of a PH₃ dopant precursor can be between about 0 sccm to about 200 sccm, a flowrate of an AsH₃ dopant precursor can be between about 0 sccm to about 450 sccm, and a flowrate of a SbH₃ dopant precursor can be between about 0 sccm to about 450 sccm. In some embodiments, during the CVD process or the PECVD process for forming diffusion barrier structures 250, a pressure can be controlled to be about 5 torr to about 300 torr, and a temperature can be controlled to be about 650° C. to about 680° C.

In some embodiments, in the process of forming diffusion barrier structures 250, the semiconductor material with the crystalline structure is initially grown epitaxially on the side surfaces of NS layers 120 along a horizontal direction (e.g., along the x-axis). Subsequently, with a certain amount of the semiconductor material formed on the side surface of NS layers 120, the semiconductor material can also be epitaxially grown along vertical directions (e.g., along the z-axis) across edges of the side surfaces of NS layers 120 and can further extend over side surfaces of inner spacer structures 130. The process can be continued such that the portion of semiconductor material over side surfaces of inner spacer structures 130 can further be epitaxially grown along the horizontal direction and towards inner spacer structures 130, such that diffusion barrier structures 250 are in contact with inner spacer structures 130. In operation 425, a time of epitaxially growing diffusion barrier structures 250 can be controlled to ensure that diffusion barrier structures 250 extend over the side surfaces of inner spacer structures 130 or in contact with the side surfaces of inner spacer structures 130.

In some embodiments, as described with reference to FIG. 11B, diffusion barrier structures 350 can be formed on exposed side surfaces of NS layers 120. The description of the process of forming diffusion barrier structures 250 is applied to a process of forming diffusion barrier structures 350, unless otherwise mentioned. In some embodiments, diffusion barrier structures 350 can be epitaxially grown starting on side surfaces of NS layers 120 and then over inner spacer structures 130. In some embodiments, the process of forming diffusion barrier structures 350 can be continued such that portions of diffusion barrier structures 350 initially grown from adjacent NS layers 120 can merge with each other over side surfaces of inner spacer structures 130. In some embodiments, a time of epitaxially growing diffusion barrier structures 350 can be controlled to be longer than the time of epitaxially growing diffusion barrier structures 250 to ensure that diffusion barrier structures 350 merge over side surfaces of inner spacer structures 130. In some embodiments, since diffusion barrier structures 350 start growing from side surfaces of NS layers 120, portions of diffusion barrier structures 350 around horizontal levels of NS layers 120 can protrude more into openings 840, compared with portions of diffusion barrier structures 350 around horizontal levels of inner spacer structures 130.

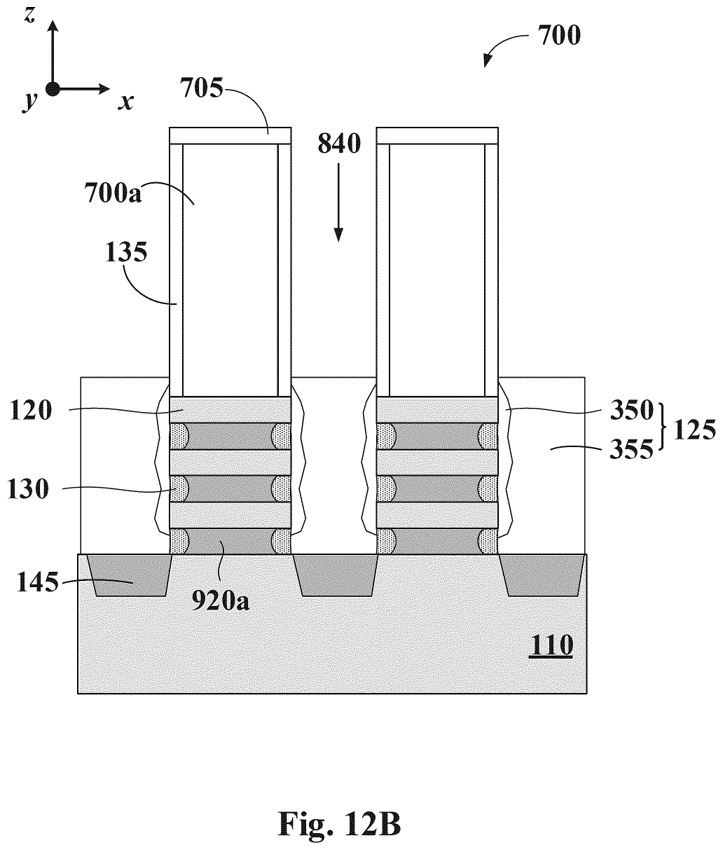

In order to form diffusion barrier structures 350 with flatter topography of side surfaces exposed in openings 840, in some embodiments, an etching process can be combined with the epitaxial growth to trim the side surfaces of diffusion barrier structures 350. For example, a flowrate of the etching gases can be increase closed to the end of forming diffusion barrier structures 350 to trim the side surfaces of diffusion barrier structures 350. Preventing diffusion barrier structures 350 from protruding too much into openings 840 can provide more space for the subsequently formed high doping regions 355 and reduce the total resistivity of the subsequently completed S/D epitaxial structures 125, as described with reference to FIG. 12B.

In referring to FIG. 4, method 400 continues with operation 430 and the process of forming high doping regions of S/D epitaxial structures in the opening. By way of example and not limitation, high doping regions 255 and 355 can be formed by epitaxially growing the semiconductor material on exposed surfaces of diffusion barrier structures 250 and 350, respectively, as described with reference to FIGS. 12A and 12B, to complete the formation of S/D epitaxial structures 125.

In some embodiments, as described with reference to FIG. 12A, high doping regions 255 can be epitaxially grown with a CVD process or a PECVD process similar to the one used in operation 425 to diffusion barrier structures 250, unless mentioned otherwise. In some embodiments, diffusion barrier structures 250 and high doping regions 255 can be sequentially formed without a vacuum break (e.g., in-situ) to avoid the formation of any intervening layers. In some embodiments, precursor gases (e.g., SiH₄, SiH₂Cl₂, SiHCl₃, and/or a combination thereof) can be used to epitaxially grow the semiconductor material (e.g., Si) on exposed surfaces of diffusion barrier structures 250. In some embodiments, flowrates of the precursor gases can be controlled. For example, a flowrate of a SiH₄ precursor gas can be between about 20 sccm to about 150 sccm, a flowrate of a SiH₂Cl₂ precursor gas can be between about 300 sccm to about 900 sccm, and a flowrate of a SiHCl₃ precursor gas can be between about 300 sccm to about 900 sccm. In some embodiments, etching gases (e.g., hydrogen chloride (HCl)) can be used to selectively remove the semiconductor material with an amorphous structure formed on dielectric surfaces (e.g., side surfaces of inner spacer structure 130 or gate spacer 135). In some embodiments, flowrates of the etching gases can be controlled. For example, a flowrate of a HCl etching gas can be between about 0 sccm to about 600 sccm. Removing the semiconductor material with the amorphous structure can ensure that the crystal structure of high doping regions 255 is crystalline. In some embodiments, dopant precursor gases, such as phosphanes (PH₃), arsanes (AsH₃), stibane (SbH₃), and/or a combination thereof can be used in the CVD process or the PECVD process to dope diffusion barrier structures 250. In some embodiments, flowrates of the dopant precursor gases can be controlled. For example, a flowrate of a PH₃ dopant precursor can be between about 30 sccm to about 450 sccm, a flowrate of an AsH₃ dopant precursor can be between about 0 sccm to about 270 sccm, and a flowrate of a SbH₃ dopant precursor can be between about 0 sccm to about 270 sccm. In some embodiments, high doping regions 255 can be doped with a dopant concentration higher than that of the diffusion barrier structures 250 by controlling flowrates of the precursor gases and the dopant precursor gases. In some embodiments, a ratio between a flowrate of the dopant precursor gases and a flowrate of the precursor gases used during the epitaxial growth of high doping regions 255 can be greater than a ratio between a flowrate of the dopant precursor gases and a flowrate of the precursor gases used during the epitaxial growth of diffusion barrier structures 250 by a factor between about 2 and about 50. In some embodiments, during the CVD process or the PECVD process for forming high doping regions 255, a pressure can be controlled to be about 100 torr to about 300 torr, and a temperature can be controlled to be about 650° C. to about 700° C.

As described with reference to FIG. 12A, in some embodiments, a time of epitaxially growing high doping regions 255 can be controlled to ensure that different portions of high doping regions 255 grown on different surfaces of diffusion barrier structures 250 merge with each other. In some embodiments, the time of epitaxially growing high doping regions 255 can be controlled to ensure that high doping regions 255 are in contact with side surfaces of inner spacer structures 130. In some embodiments, the time of epitaxially growing high doping regions 255 can be controlled to ensure that high doping regions 255 are in contact with isolation layers 145 on the bottom surface of openings 840. In some embodiments, the time of epitaxially growing high doping regions 255 can be controlled to ensure that high doping regions 255 are formed above the topmost points of diffusion barrier structures 250. In some embodiments, the time of epitaxially growing high doping regions 255 can be controlled to ensure that high doping regions 255 are in contact with gate spacers 135 at interfaces above the interfaces between diffusion barrier structures 250 and gate spacers 135.

In some embodiments, as described with reference to FIG. 12B, high doping regions 355 can be epitaxially grown with a CVD process or a PECVD process similar to the one used in operation 425 to form diffusion barrier structures 350, unless mentioned otherwise. The description of forming high doping regions 255 as described with reference to FIG. 12A applies to forming high doping regions 355, unless mentioned otherwise. As described with reference to FIG. 12B, in some embodiments, since diffusion barrier structures 350 may not entirely cover some of the side surfaces of inner spacer structures 130, high doping regions 355 may not be in contact with these side surfaces of inner spacer structures 130.

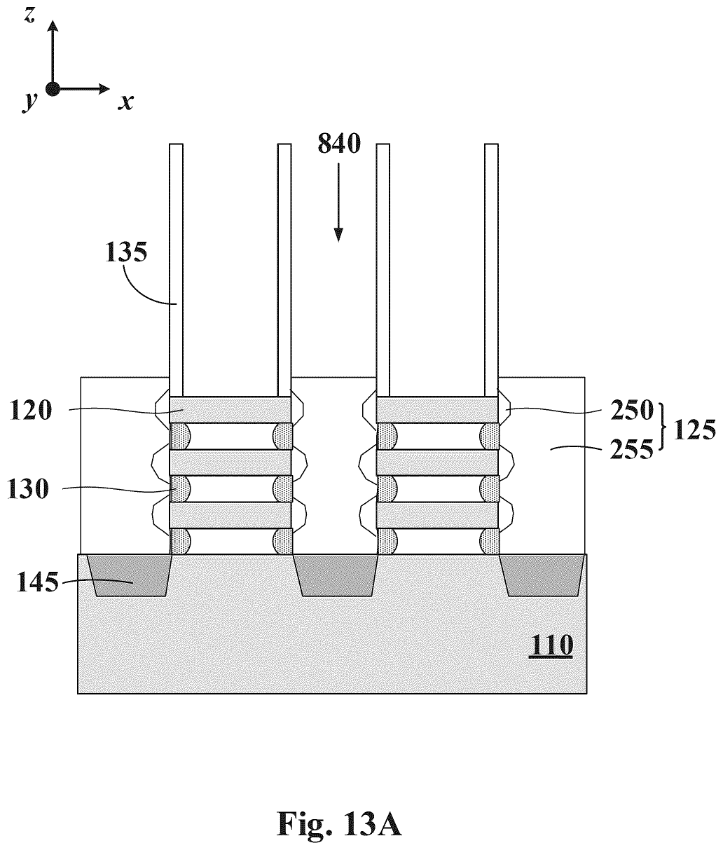

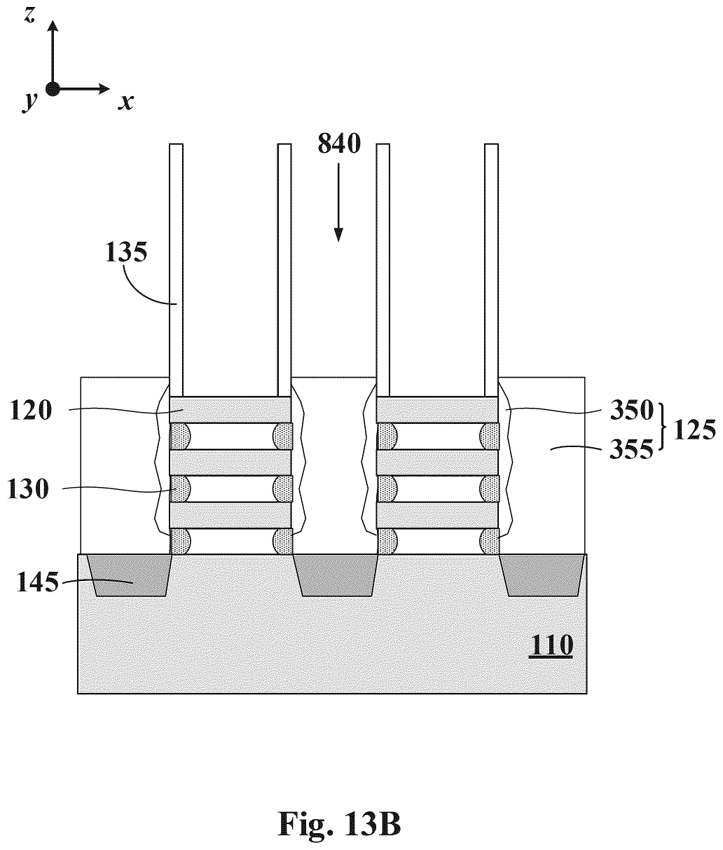

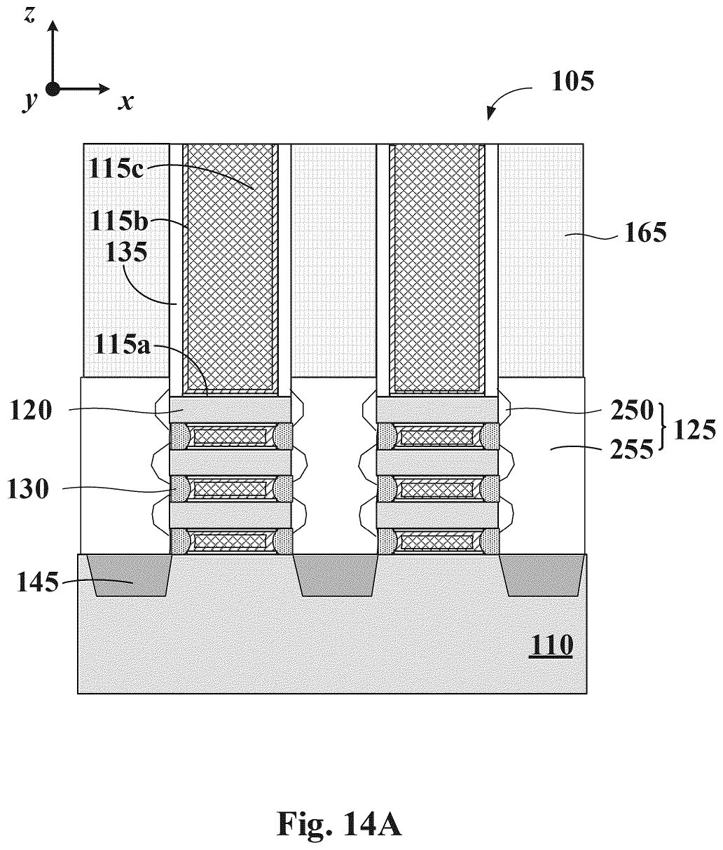

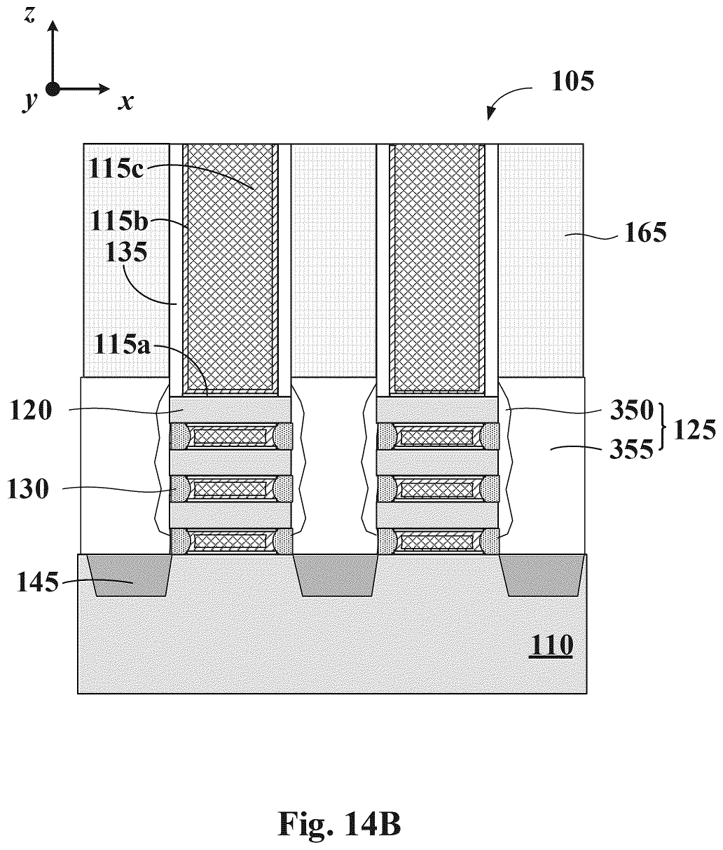

In referring to FIG. 4, method 400 continues with operation 435 and the process of forming metal gate structures. The process of forming metal gate structures can include (i) removing sacrificial gate structures 700 and first NS layers 920a, as described with reference to FIGS. 13A and 13B, and (ii) forming metal gate structures 115 to surround second NS layers 120, as described with reference to FIGS. 14A and 14B.

In some embodiments, removing sacrificial gate structures 700 can include removing capping layer 705 to expose sacrificial gate electrode 700a, and subsequently, removing sacrificial gate electrode 700a to expose fin structures 620 between S/D epitaxial structures 125. In some embodiments, removing first NS layers 920a can include selectively etching first NS layers 920a without removing NS layers 120 as described with reference to FIGS. 13A and 13B.

In some embodiments, forming metal gate structures 115 can include (i) forming interfacial dielectric layer 115a on exposed surfaces of second NS layers 120, (ii) forming gate dielectric layer 115b on interfacial dielectric layer 115a, and (iii) forming gate electrode 115c on gate dielectric layer 115b, as described with reference to FIGS. 14A and 14B. As discussed above, metal gate structures 115 are electrically isolated from S/D epitaxial structures 125 by inner spacer structures 130 and gate spacers 135. In some embodiments, after forming metal gate structures 115, ILD layer 165 can be formed to fill the space above S/D epitaxial structures 125.

The embodiments described herein are directed to structures of a GAAFET and methods of forming the structures. In some embodiments, a structure includes a diffusion barrier structure in an S/D epitaxial structure of the GAAFET. The diffusion barrier structure is in contact with an NS layer of the GAAFET and extends over an inner spacer structure adjacent to the NS layer. The diffusion barrier structure separates a high doping region of the S/D epitaxial structure from the NS layer and regions of the inner spacer structure close to the NS layer and prevents (or mitigates) dopants in the high doping region from diffusing into the NS layer and the inner spacer structure, thus preserving the integrity of the NS layer as a semiconducting channel of the GAAFET and avoiding a current crowding effect.

In some embodiments, a structure includes nanostructure element formed on a substrate, a gate structure surrounding the nanostructure element, and an inner spacer structure abutting (or in contact with) the gate structure. The structure further includes a first epitaxial layer and a second epitaxial layer. The first epitaxial layer is in contact with a side surface of the nanostructure element and over a side surface of the inner spacer structure. The second epitaxial layer is in contact with the first epitaxial layer. A dopant concentration of the first epitaxial layer is less than a dopant concentration of the second epitaxial layer.

In some embodiments, a structure includes nano-sheet layers formed on a substrate, a gate structure surrounding the nano-sheet layers, and an inner spacer structure interposed between the gate structure and the nano-sheet layers. The structure further includes source/drain (S/D) structure on the substrate and adjacent to the nano-sheet layers. The S/D structure includes a diffusion barrier structure and an epitaxial layer. The diffusion barrier structure is in contact with side surfaces of the nano-sheet layers and a side surface of the inner spacer structure. The epitaxial layer is on the substrate and separated from the nano-sheet layers by the diffusion barrier structure.

In some embodiments, a method includes forming channel layers alternately stacked with sacrificial layers on a substrate, removing a portion of each of the sacrificial layers to form a recess structures, and forming inner spacers in the recess structures. The method further includes forming a diffusion barrier structure in contact with side surfaces of the channel layers and over side surfaces of the inner spacers, and forming an epitaxial region over side surfaces of the diffusion barrier structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a nanostructure element on a substrate;
a gate structure surrounding the nanostructure element;
an inner spacer structure abutting the gate structure;
a first epitaxial layer in contact with a side surface of the nanostructure element and over a side surface of the inner spacer structure; and
a second epitaxial layer in contact with the first epitaxial layer, wherein a dopant concentration of the first epitaxial layer is less than a dopant concentration of the second epitaxial layer.

2. The structure of claim 1, further comprising a gate spacer on the nanostructure element, wherein the first epitaxial layer is over a side surface of the gate spacer.

3. The structure of claim 2, wherein an interface between the gate spacer and the second epitaxial layer is above another interface between the gate spacer and the first epitaxial layer.

4. The structure of claim 1, wherein a vertical length of the first epitaxial layer is greater than a thickness of the nanostructure element.

5. The structure of claim 1, wherein the first epitaxial layer is over an edge of an interface between the nanostructure element and the gate structure.

6. The structure of claim 1, wherein the side surface of the inner spacer structure is in contact with a portion of a side surface of the first epitaxial layer and a side surface of the second epitaxial layer.

7. The structure of claim 1, wherein the first epitaxial layer extends from a top edge of the side surface of the inner spacer structure to a bottom edge of the side surface of the inner spacer structure.

8. A structure, comprising:
a plurality of nano-sheet layers on a substrate;
a gate structure surrounding the plurality of nano-sheet layers;
an inner spacer structure interposed between the plurality of nano-sheet layers; and
a source/drain (S/D) structure on the substrate and adjacent to the plurality of nano-sheet layers, wherein the S/D structure comprises:
a diffusion barrier structure in contact with side surfaces of the plurality of nano-sheet layers and a side surface of the inner spacer structure; and
an epitaxial layer on the substrate and separated from the plurality of nano-sheet layers by the diffusion barrier structure.

9. The structure of claim 8, wherein a dopant concentration of the epitaxial layer is greater than a dopant concentration of the diffusion barrier structure.

10. The structure of claim 9, wherein the dopant concentration of the diffusion barrier structure is between about 1×10²⁰ cm⁻³ and about 2×10²¹ cm⁻³.

11. The structure of claim 9, wherein the dopant concentration of the epitaxial layer is between about 5×10²⁰ cm⁻³ and about 5×10²¹ cm⁻³.

12. The structure of claim 8, wherein the diffusion barrier structure comprises phosphorous, arsenic, antimony, or a combination thereof.

13. The structure of claim 8, wherein the diffusion barrier structure extends from a top edge of the side surface of the inner spacer structure to a bottom edge of the side surface of the inner spacer structure.

14. The structure of claim 8, wherein:
the side surface of the inner spacer structure is in contact with first and second side surfaces of the diffusion barrier structure; and
the side surface of the inner spacer structure is in contact with a side surface of the epitaxial layer; and
the side surface of the epitaxial layer is in contact with the first and second side surfaces of the diffusion barrier structure.

15. A method, comprising:
forming, on a substrate, a plurality of channel layers alternately stacked with a plurality of sacrificial layers;
removing a portion of each of the plurality of sacrificial layers to form a plurality of recess structures;
forming a plurality of inner spacers in the plurality of recess structures;
forming a diffusion barrier structure in contact with side surfaces of the plurality of channel layers and over side surfaces of the plurality of inner spacers; and
forming an epitaxial region over side surfaces of the diffusion barrier structure.

16. The method of claim 15, further comprising forming a gate spacer on the plurality of channel layers, wherein forming the diffusion barrier structure comprises epitaxially growing the diffusion barrier structure over a side surface of the gate spacer.

17. The method of claim 16, wherein forming the epitaxial region comprises growing the epitaxial region over the side surface of the gate spacer and above the diffusion barrier structure.

18. The method of claim 15, wherein forming the diffusion barrier structure comprises epitaxially growing a semiconductor material to cover interfaces between the plurality of channel layers and the plurality of inner spacers.

19. The method of claim 15, wherein forming the diffusion barrier structure comprises:
growing a first portion of the diffusion barrier structure on a side surface of a first channel layer of the plurality of channel layers;
growing a second portion of the diffusion barrier structure on a side surface of a second channel layer of the plurality of channel layers; and
merging the first and second portions of the diffusion barrier structure over a side surface of an inner spacer between the first and second channel layers.

20. The method of claim 15, wherein:
forming the diffusion barrier structure comprises doping the diffusion barrier structure with a first dopant concentration; and
forming the epitaxial region comprises doping the epitaxial region with a second dopant concentration greater than the first dopant concentration.
